(19) United States
(12) Patent Application Publication
(10) Pub. No.: US 2024/0213431 A1
(43) Pub. Date: Jun. 27, 2024

(54) DISPLAY DEVICE

(71) Applicant: LG Display Co., Ltd., Seoul (KR)

(72) Inventors: GiSang HONG, Seoul (KR); EunHye LEE, Paju-si (KR); Jungmin KIM, Paju-si (KR)

(73) Assignee: LG Display Co., Ltd., Seoul (KR)

(21) Appl. No.: 18/516,581

(22) Filed: Nov. 21, 2023

(30) Foreign Application Priority Data
Dec. 27, 2022 (KR) 10-2022-0185419

(51) Int. Cl. H01L 33/62; H01L 25/075; H01L 25/16; H01L 27/12

(52) U.S. Cl. CPC H01L 33/62; H01L 25/0753; H01L 25/167; H01L 27/124; H01L 27/1255

(57) ABSTRACT

According to an aspect of the present disclosure, a display device includes a substrate having an active area and a non-active area where sub pixels are disposed in the active area, a first assembly line and a second assembly line disposed in the sub pixels and being separated from each other to form a separated space, a light emitting diode disposed in the sub pixels and disposed on the first assembly line and the second assembly line, and a capacitor disposed below the first assembly line and the second assembly line. The capacitor is disposed so as to overlap the separated space formed between the first assembly line and the second assembly line. By this configuration, the light extraction of the display device can be improved.

### CROSS-REFERENCE TO RELATED APPLICATIONS

This application claims priority to Korean Patent Application No. 10-2022-0185419 filed on Dec. 27, 2022, in the Korean Intellectual Property Office, the disclosure of which is hereby expressly incorporated by reference into the present application.

### BACKGROUND

### Field

The present disclosure relates to a display device, and more particularly, to a display device using a light emitting diode (LED).

### Discussion of the Related Art

Among display devices which are used for a monitor of a computer, a television, or a cellular phone, there exist an organic light emitting display (OLED) device which is a self-emitting device and a liquid crystal display (LCD) device which needs a separate light source.

An applicable range of the display device can be diversified to include personal digital assistants as well as monitors of computers and televisions, and a display device with a large display area and a reduced volume and weight is being studied.

In recent years, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device.

Further, the LED has a fast lighting speed, excellent luminous efficiency, and a strong impact resistance so that a stability is excellent and an image having a high luminance can be displayed.

### SUMMARY OF THE DISCLOSURE

An object to be achieved by the present disclosure is to provide a display device which reduces leakage of light from a light emitting diode between assembly lines.

Another object to be achieved by the present disclosure is to provide a display device with an increased/improved resolution.

Still another object to be achieved by the present disclosure is to provide a display device with an improved production yield.

Still another object to be achieved by the present disclosure is to provide a display device with an improved assembly rate of a light emitting diode.

Objects of the present disclosure are not limited to the above-mentioned objects, and other objects, which are not mentioned above, can be clearly understood by those skilled in the art from the following descriptions.

According to an aspect of the present disclosure, a display device includes a substrate including an active area in which a plurality of sub pixels is disposed and a non-active area; a first assembly line and a second assembly line which are disposed in the plurality of sub pixels on the substrate and are spaced apart from each other; a light emitting diode which is disposed in the plurality of sub pixels and is disposed on the first assembly line and the second assembly line; and a capacitor disposed below the first assembly line and the second assembly line, and the capacitor is disposed so as to overlap a space between the first assembly line and the second assembly line. By this configuration, the light extraction of the display device can be improved.

Other detailed matters of the exemplary embodiments are included in the detailed description and the drawings.

According to an aspect of the present disclosure, a light extraction efficiency of the light emitting diode can be improved.

According to an aspect of the present disclosure, an assembly rate of a light emitting diode which is disposed by a self-assembling method can be improved.

According to an aspect of the present disclosure, a resolution of the display device can be improved by disposing the assembly line, the light emitting diode and the storage capacitor to be overlapped.

According to an aspect of the present disclosure, a capacitance of the storage capacitor can be increased by overlapping the assembly line, the light emitting diode and the storage capacitor.

The effects according to embodiments of the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2 is a pixel circuit diagram of a display device according to an exemplary embodiment of the present disclosure;

FIG. 3 is an enlarged plan view of a display device according to an exemplary embodiment of the present disclosure;

FIG. 4 is a cross-sectional view taken along line IV-IV′ of FIG. 3;

FIG. 5 is a schematic diagram of a display device according to another exemplary embodiment of the present disclosure; and

FIG. 6 is a schematic diagram for explaining a manufacturing process according to another exemplary embodiment of the present disclosure.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The term “exemplary” or “exemplarily” is used to mean an example, and is interchangeably used with the term “example”. Further, embodiments are example embodiments and aspects are example aspects. Any implementation described herein as an “exemplary”, “exemplarily” or “example” is not necessarily to be construed as preferred or advantageous over other implementations.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “comprising,” “including,” “having,” and “consist of,” etc. used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “over”, “below”, and “next”, etc., one or more parts can be positioned between the two parts unless the terms are used with the term “immediately” or “directly”.

When an element or layer is disposed “on” another element or layer, another layer or another element can be interposed directly on the other element or layer or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings. Since scales of components shown in the drawings have different scales from actual ones for convenience of explanation, they are not limited to the scales shown in the drawings. Further, all the components of each display device or each display apparatus according to all embodiments of the present disclosure are operatively coupled and configured.

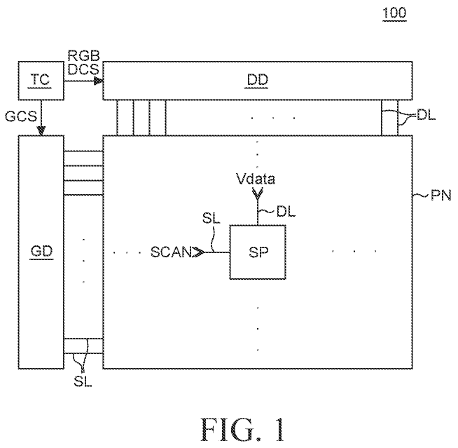

FIG. 1 is a schematic plan view of a display device according to an exemplary embodiment of the present disclosure.

In FIG. 1, for the convenience of description, among various components of a display device 100, a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The display panel PN is a configuration which displays images to the user and includes the plurality of sub pixels SP. In the display panel PN, a plurality of scan lines SL and a plurality of data lines DL intersect each other and each of the plurality of sub pixels SP is connected to the corresponding scan line SL and the corresponding data line DL, respectively. In addition, each of the plurality of sub pixels SP can be connected to a high potential power line VDD, a low potential power line VSS, and a reference line RL. The display panel can include an active area and a non-active area adjacent to the active area, where the active area displays images and the non-active area does not display images.

The plurality of sub pixels SP is a minimum unit which configures a screen and each of the plurality of sub pixels SP includes a light emitting diode (LED) and a pixel circuit for driving the light emitting diode. The plurality of light emitting diodes can be defined in different manners depending on the type of the display panel PN. For example, when the display panel PN is an inorganic light emitting display panel, the light emitting diode can be an LED or a micro light emitting diode (micro LED).

The gate driver GD supplies a plurality of scan signals SCAN to a plurality of scan lines SL in accordance with a plurality of gate control signals GCS supplied from the timing controller TC. Even though in FIG. 1, it is illustrated that one gate driver GD is disposed to be spaced apart from one side of the display panel PN, the number of the gate drivers GD and the placement thereof are not limited thereto. For example, the gate driver GD can be disposed in the active area. The non-active area can surround the active area entirely or only in part, and one or more non-active areas can be provided adjacent or surrounding the active area. The shapes of the active area and non-active area can be rectangular, but other shapes are possible.

The data driver DD converts image data RGB input from the timing controller TC into a data voltage Vdata in accordance with a plurality of data control signals DCS supplied from the timing controller TC by using a reference gamma voltage. The data driver DD can supply the converted data voltage Vdata to the plurality of data lines DL.

The timing controller TC aligns image data RGB input from the outside to supply the aligned image data to the data driver DD. The timing controller TC can generate a gate control signal GCS and a data control signal DCS using synchronization signals input from the outside, such as a dot clock signal, a data enable signal, and horizontal/vertical synchronization signals. The timing controller TC supplies the generated gate control signal GCS and data control signal DCS to the gate driver GD and the data driver DD, respectively, to control the gate driver GD and the data driver DD.

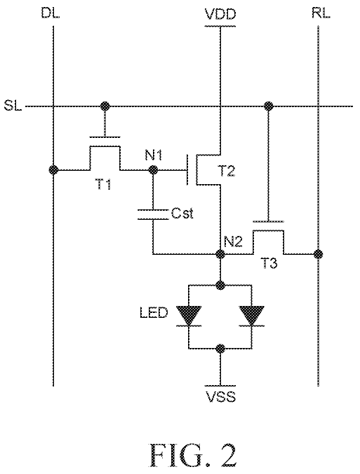

Hereinafter, the display panel PN of the display device 100 will be described in more detail with reference to FIGS. 2 to 4 together.

FIG. 2 is a pixel circuit diagram of a display device according to an exemplary embodiment of the present disclosure.

Referring to FIG. 2, each of the plurality of sub pixels SP in the panel 100 can include a first transistor T1, a second transistor T2, a third transistor T3, a storage capacitor Cst, and a light emitting diode LED. In order to drive the pixel circuit, a plurality of wiring lines including a data line DL, a high potential power line VDD, a scan line SL, and a reference line RL is disposed on a first substrate 110.

Each of the first transistor T1, the second transistor T2, and the third transistor T3 included in the pixel circuit of one sub pixel SP includes a gate electrode, a source electrode, and a drain electrode.

The first transistor T1, the second transistor T2, and the third transistor T3 can be P-type thin film transistors or N-type thin film transistors. For example, since in the P-type thin film transistor, holes flow from the source electrode to the drain electrode, the current can flow from the source electrode to the drain electrode. Since in the N-type thin film transistor, electrons flow from the source electrode to the drain electrode, the current can flow from the drain electrode to the source electrode. Hereinafter, the description will be made under the assumption that the first transistor T1, the second transistor T2, and the third transistor T3 are N-type thin film transistors in which the current flows from the drain electrode to the source electrode, but the present disclosure is not limited thereto.

The first transistor T1 includes a first active layer, a first gate electrode, a first source electrode, and a first drain electrode. The first gate electrode is connected to the scan line SL, the first source electrode is connected to the first node N1, and the first drain electrode is connected to a data line DL. The first transistor T1 can be turned on or turned off based on a scan signal SCAN from the scan line SL. When the first transistor T1 is turned on, the scan signal SCAN from the scan line SL can be charged in the first node N1. Therefore, the first transistor T1 which is turned on or turned off by the scan line SL can also be referred to as a switching transistor.

The second transistor T2 includes a second active layer, a second gate electrode, a second source electrode, and a second drain electrode. The second gate electrode is connected to a first node N1, the second source electrode is connected to the light emitting diode LED, and the second drain electrode is connected to the high potential power line VDD. When a voltage of the first node N1 is higher than a threshold voltage, the second transistor T2 is turned on, and when the voltage of the first node N1 is lower than the threshold voltage, the second transistor T2 can be turned off. When the second transistor T2 is turned on, a driving current can be transmitted to the light emitting diode LED by means of the second transistor T2. Therefore, the second transistor T2 which controls the driving current to be transmitted to the light emitting diode LED can also be referred to as a driving transistor.

The third transistor T3 includes a third active layer, a third gate electrode, a third source electrode, and a third drain electrode. The third gate electrode is connected to the scan line SL, the third source electrode is connected to the second node N2, and the third drain electrode is connected to the reference line RL. The third transistor T3 can be turned on or turned off based on a scan signal SCAN from the scan line SL. When the third transistor T3 is turned on, a reference voltage from the reference line RL can be transmitted to the second node N2 and the storage capacitor Cst. Therefore, the third transistor T3 can also be referred to as a sensing transistor.

The storage capacitor Cst is connected between the second gate electrode and the second source electrode of the second transistor T2. For example, the storage capacitor Cst can be connected between the first node N1 and the second node N2. The storage capacitor Cst maintains a potential difference between the second gate electrode and the second source electrode of the second transistor T2 while the light emitting diode LED emits light, so that a constant driving current can be supplied to the light emitting diode LED. The storage capacitor Cst includes a plurality of capacitor electrodes and for example, one of the plurality of capacitor electrodes is connected to the first node N1 and another one can be connected to the second node N2.

The plurality of light emitting diodes LED can be connected in parallel. At this time, the plurality of light emitting diodes LED is connected to the second node N2 and the low potential power line VSS. Therefore, the light emitting diode LED is supplied with a driving current from the first transistor T1 to emit light.

In the meantime, in FIG. 2, it is described that the pixel circuit of the sub pixel SP of the display device 100 according to the exemplary embodiment of the present disclosure has a 3T1C structure including three transistors and one storage capacitor Cst. However, the number and a connection relationship of the transistors and storage capacitors Cst can vary in various ways depending on the design and are not limited thereto.

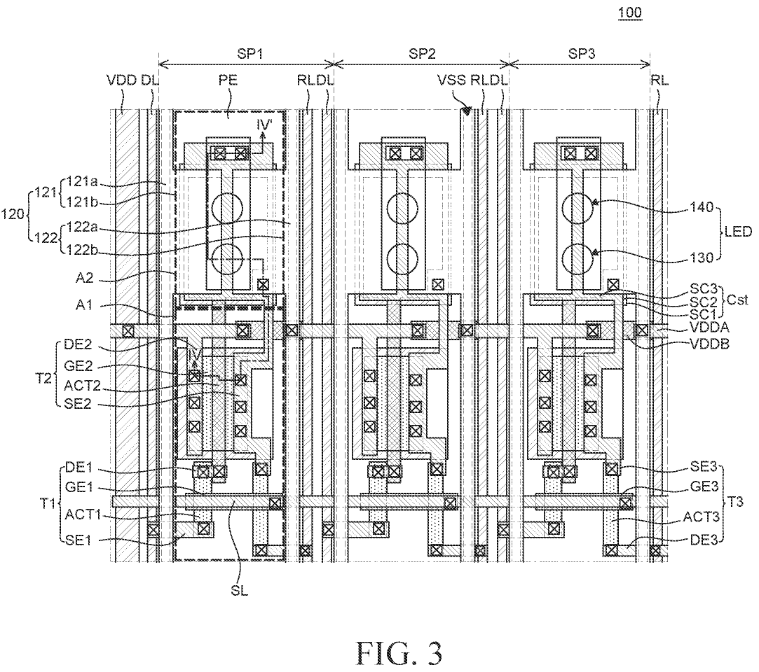

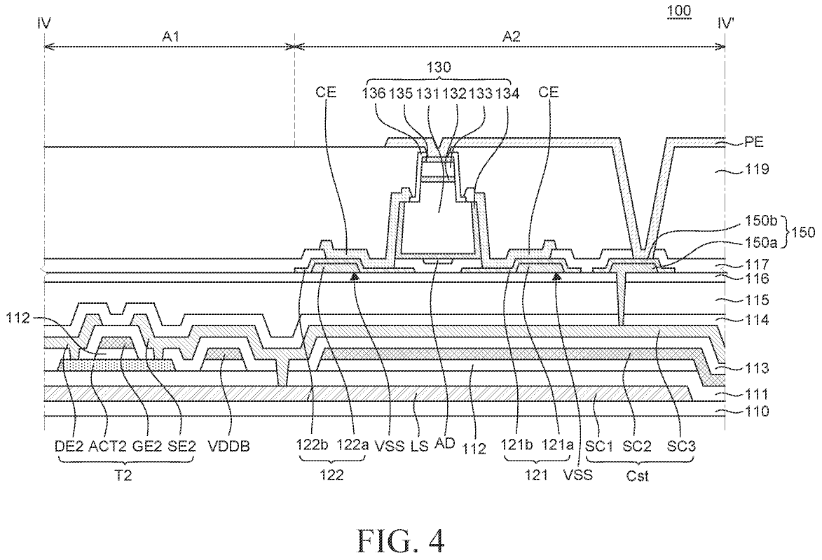

FIG. 3 is an enlarged plan view of a display device according to an exemplary embodiment of the present disclosure. FIG. 4 is a cross-sectional view taken along line IV-IV′ of FIG. 3. In FIG. 3, for the simplicity of the drawing, the hatching of the assembly line 120 and the light emitting diode LED is omitted and the contact electrode CE is not illustrated.

Referring to FIG. 3, the display device 100 includes a first sub pixel SP1 disposed in a first column, a second sub pixel SP2 disposed in a second column, and a third sub pixel SP3 disposed in a third column which are repeatedly disposed in the row direction.

Each of the first sub pixel SP1, the second sub pixel SP2, and the third sub pixel SP3 includes a light emitting diode LED and a pixel circuit to independently emit light. For example, the first sub pixel SP1 is a red sub pixel, the second sub pixel SP2 is a green sub pixel, and the third sub pixel SP3 can be a blue sub pixel, but it is not limited thereto. Referring to FIG. 3, the plurality of sub pixels SP includes a first area A1 in which a plurality of pixel circuits is disposed and a second area A2 which extends from the first area A1 and has a storage capacitor Cst disposed therein.

The pixel circuit can include a first transistor T1, a second transistor T2, and a third transistor T3. The storage capacitor Cst can be formed of a metal material having excellent reflection efficiency, such as aluminum (Al) or silver (Ag), so as to be disposed in an area overlapping the plurality of light emitting diodes LED to reflect light emitted from the light emitting diode LED to be upwardly extracted.

The display panel PN includes the substrate 110, a buffer layer 111, a gate insulating layer 112, an interlayer insulating layer 113, a first passivation layer 114, a lower planarization layer 115, a second passivation layer 116, a third passivation layer 117, and an upper planarization layer 119.

The substrate 110 is a component for supporting various components included in the display panel PN and can be formed of an insulating material. For example, the substrate 110 can be formed of glass or resin. Further, the substrate 110 can be configured to include polymer or plastic or can be formed of a material having flexibility.

A high potential power line VDD, a plurality of data lines DL, a reference line RL, an assembly line 120, a light shielding layer LS, and a first capacitor electrode SC1 are disposed on the substrate 110.

The high potential power line VDD is a wiring line which transmits a high potential power voltage to each of the plurality of sub pixels SP. The plurality of high potential power lines VDD can transmit the high potential power voltage to a second transistor T2 of each of the plurality of sub pixels SP. The high potential power line VDD can extend along a column direction between the plurality of sub pixels SP. For example, the high potential power line VDD can be disposed to extend along a column direction between the first sub pixel SP1 and the third sub pixel SP3. The high potential power line VDD can transmit a high potential power voltage to each of the plurality of sub pixels SP disposed in the row direction through a first auxiliary high potential power line VDDA and a second auxiliary high potential power line VDDB to be described below. In this case, the high potential power line VDD can be referred to as a first power line. The column direction is referred to as a first direction and the row direction can be referred to as a second direction.

The plurality of data lines DL is wiring lines which transmit the data voltage Vdata to each of the plurality of sub pixels SP. The plurality of data lines DL can be connected to the first transistor T1 of each of the plurality of sub pixels SP. The plurality of data lines DL can extend along a column direction between the plurality of sub pixels SP. For example, a data line DL which extends between the first sub pixel SP1 and the high potential power line VDD in the column direction transmits a data voltage Vdata to the first sub pixel SP1. A data line DL disposed between the first sub pixel SP1 and the second sub pixel SP2 transmits a data voltage Vdata to the second sub pixel SP2. Further, a data line DL disposed between the third sub pixel SP3 and the high potential power line VDD can transmit a data voltage Vdata to the third sub pixel SP3.

The reference lines RL is a wiring line which transmits a reference voltage to each of the plurality of sub pixels SP. The reference line RL can be connected to the third transistor T3 of each of the plurality of sub pixels SP. The reference line RL can extend along a column direction between the plurality of sub pixels SP. For example, the reference line RL extending between the first sub pixel SP1 and the second sub pixel SP2 in the column direction transmits the reference voltage to the first sub pixel SP1. The reference line RL disposed between the second sub pixel SP2 and the third sub pixel SP3 transmits the reference voltage to the second sub pixel SP2, and the reference line RL disposed between the third sub pixel SP3 and the first sub pixel SP1 can transmit the reference voltage to the third sub pixel SP3. A third drain electrode DE3 of the third transistor T3 of each of the first sub pixel SP1, the second sub pixel SP2, and the third sub pixel SP3 extends in the row direction to be electrically connected to the reference line RL. In this case, the reference line RL can be referred to as a third power line.

The light shielding layer LS is disposed on the substrate 110 in each of the plurality of sub pixels SP. The light shielding layer LS can be disposed in the first area A1 and the second area A2.

The light shielding layer LS disposed in the first area A1 blocks light which is incident to the transistor from the lower portion of the substrate 110 to minimize a leakage current. For example, the light shielding layer LS can block light incident to a second active layer ACT2 of the second transistor T2 which is a driving transistor.

The light shielding layer LS disposed in the second area A2 can be spaced apart from the light shielding layer LS disposed in the first area A1. The light shielding layer LS disposed in the second area A2 can serve as one electrode of the storage capacitor Cst.

Referring to FIGS. 3 and 4, the storage capacitor Cst can be disposed so as to overlap the light emitting diode LED. The storage capacitor Cst can be disposed so as to overlap a separated space between a first assembly line 121 and a second assembly line 122 which are disposed to be adjacent to each other in one sub pixel SP.

In each of the plurality of sub pixels SP, a first capacitor electrode SC1 is disposed on the substrate 110. The first capacitor electrode SC1 can form a storage capacitor Cst together with the other capacitor electrode. The first capacitor electrode SC1 can be disposed on the same layer as the light shielding layer LS. For example, the first capacitor electrode SC1 is spaced apart from the light shielding layer LS disposed in the second area A2, but can be formed of the same material on the same layer as the light shielding layer LS disposed in the second area A2.

The buffer layer 111 is disposed on the high potential power line VDD, the plurality of data lines DL, the reference line RL, the light shielding layer LS, and the first capacitor electrode SC1. The buffer layer 111 can reduce permeation of moisture or impurities through the substrate 110. The buffer layer 111 can be configured by a single layer or a plurality of layers of silicon oxide (SiOx) or silicon nitride (SiNx), but is not limited thereto. However, the buffer layer 111 can be omitted depending on a type of substrate 110 or a type of transistor, but is not limited thereto.

First, the first transistor T1 is disposed on the buffer layer 111 in each of the plurality of sub pixels SP. The first transistor T1 is a transistor which transmits a data voltage Vdata to the second gate electrode GE2 of the second transistor T2. A data voltage Vdata from the data line DL can be transmitted to the second gate electrode GE2 of the second transistor T2 through the turned-on first transistor T1.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 can be formed of a semiconductor material such as an oxide semiconductor, amorphous silicon, or polysilicon, but is not limited thereto.

The gate insulating layer 112 is disposed on the first active layer ACT1. The gate insulating layer 112 is an insulating layer which insulates the first active layer ACT1 from the first gate electrode GE1 and can be configured by a single layer or a plurality of layers of silicon oxide (SiOx) or silicon nitride (SiNx), but is not limited thereto.

The first gate electrode GE1 is disposed on the gate insulating layer 112. The first gate electrode GE1 can be electrically connected to the scan line SL. The first gate electrode GE1 can be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the first gate electrode GE1. A contact hole is formed in the interlayer insulating layer 113 to allow each of the first source electrode SE1 and the first drain electrode DEI to be connected to the first active layer ACT1. The interlayer insulating layer 113 is an insulating layer which protects components below the interlayer insulating layer 113 and can be configured by a single layer or a plurality of layers of silicon oxide (SiOx) or silicon nitride (SiNx), but is not limited thereto.

A first source electrode SE1 and a first drain electrode DE1 which are electrically connected to the first active layer ACT1 are disposed on the interlayer insulating layer 113. The first drain electrode DE1 can be connected to the data line DL and the first active layer ACT1, and the first source electrode SE1 can be connected to the first active layer ACT1 and the second gate electrode GE2 of the second transistor T2. The first source electrode SE1 and the first drain electrode DE1 can be configured by a conductive material, such as copper (Cu), aluminum (Al), molybdenum (Mo), nickel (Ni), titanium (Ti), chrome (Cr), or an alloy thereof, but are not limited thereto.

The second transistor T2 is disposed on the buffer layer 111 in each of the plurality of sub pixels SP. The second transistor T2 is a transistor which supplies a driving current to the light emitting diode LED. The second transistor T2 is turned on to control the current flowing to the light emitting diode LED.

The second transistor T2 includes a second active layer ACT2, a second gate electrode GE2, a second source electrode SE2, and a second drain electrode DE2.

The second active layer ACT2 is disposed on the buffer layer 111. The second active layer ACT2 can be formed of a semiconductor material such as an oxide semiconductor, amorphous silicon, or polysilicon, but is not limited thereto.

The gate insulating layer 112 is disposed on the second active layer ACT2 and the second gate electrode GE2 is disposed on the gate insulating layer 112. The second gate electrode GE2 can be electrically connected to the first source electrode SE1 of the first transistor T1. The second gate electrode GE2 can be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the second gate electrode GE2, and the second source electrode SE2 and the second drain electrode DE2 which are electrically connected to the second active layer ACT2 are disposed on the interlayer insulating layer 113. The second drain electrode DE2 can be electrically connected to the second active layer ACT2 and the high potential power line VDD, and the second source electrode SE2 can be electrically connected to the second active layer ACT2 and the light emitting diode LED.

At this time, the second source electrode SE2 extends in the first area A1 to be disposed to overlap the second area A2. Therefore, the second source electrode SE2 can be disposed to overlap a bottom surface of the light emitting diode LED.

The second source electrode SE2 and the second drain electrode DE2 can be configured by a conductive material, such as copper (Cu), aluminum (Al), molybdenum (Mo), nickel (Ni), titanium (Ti), chrome (Cr), or an alloy thereof, but are not limited thereto.

The third transistor T3 is disposed on the buffer layer 111 in each of the plurality of sub pixels SP. The third transistor T3 is a transistor for compensating for a threshold voltage of the second transistor T2. The third transistor T3 is connected between the second source electrode SE2 of the second transistor T2 and the reference line RL. The third transistor T3 is turned on to transmit the reference voltage to the second source electrode SE2 of the second transistor T2 to sense a threshold voltage of the second transistor T2. Therefore, the third transistor T3 can sense a characteristic of the second transistor T2.

The third transistor T3 includes a third active layer ACT3, a third gate electrode GE3, a third source electrode SE3, and a third drain electrode DE3.

The third active layer ACT3 is disposed on the buffer layer 111. The third active layer ACT3 can be formed of a semiconductor material such as an oxide semiconductor, amorphous silicon, or polysilicon, but is not limited thereto.

The gate insulating layer 112 is disposed on the third active layer ACT3 and the third gate electrode GE3 is disposed on the gate insulating layer 112. The third gate electrode GE3 can be electrically connected to the scan line SL. The third gate electrode GE3 can be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the third gate electrode GE3, and the third source electrode SE3 and the third drain electrode DE3 which are electrically connected to the third active layer ACT3 are disposed on the interlayer insulating layer 113. The third drain electrode DE3 can be electrically connected to the third active layer ACT3 and the reference line RL, and the third source electrode SE3 can be electrically connected to the third active layer ACT3 and the second source electrode SE2 of the second transistor T2. The third source electrode SE3 and the third drain electrode DE3 can be configured by a conductive material, such as copper (Cu), aluminum (Al), molybdenum (Mo), nickel (Ni), titanium (Ti), chrome (Cr), or an alloy thereof, but are not limited thereto.

The second auxiliary high potential power line VDDB is disposed on the gate insulting layer 112. The second auxiliary high potential power line VDDB is disposed between the first auxiliary high potential power lines VDDA to electrically connect the first auxiliary high potential power lines VDDA which are spaced apart from each other.

The second capacitor electrode SC2 is disposed on the gate insulating layer 112. The second capacitor electrode SC2 is one of electrodes which form the storage capacitor Cst and can be disposed to overlap the first capacitor electrode SC1. The second capacitor electrode SC2 is formed on the same layer as the second gate electrode GE2 of the second transistor T2 to be formed of the same material as the second gate electrode GE2.

The first capacitor electrode SC1 and the second capacitor electrode SC2 can be disposed to be spaced apart from each other with the buffer layer 111 and the gate insulating layer 112 therebetween.

The plurality of scan lines SL, the first auxiliary high potential power line VDDA, and a third capacitor electrode SC3 are disposed on the interlayer insulating layer 113.

First, the scan line SL is a wiring line which transmits the scan signal SCAN to each of the plurality of sub pixels SP. The scan line SL can extend in the row direction while traversing the plurality of sub pixels SP. The scan line SL can be electrically connected to the first gate electrode GE1 of the first transistor T1 and the third gate electrode GE3 of the third transistor T3 of each of the plurality of sub pixels SP.

The first auxiliary high potential power line VDDA is disposed on the interlayer insulting layer 113. The first auxiliary high potential power line VDDA extends in the row direction to be disposed to traverse the plurality of sub pixels SP. The first auxiliary high potential power line VDDA can be electrically connected to the high potential power line VDD extending in the column direction and the second drain electrode DE2 of the second transistor T2 of each of the plurality of sub pixels SP disposed along the row direction.

The third capacitor electrode SC3 is disposed on the interlayer insulating layer 113. The third capacitor electrode SC3 is an electrode which forms the storage capacitor Cst, and can be disposed to overlap the first capacitor electrode SC1 and the second capacitor electrode SC2. The third capacitor electrode SC3 can be formed of the same material as the second source electrode SE2 and the second drain electrode DE2 on the same layer as the second source electrode SE2 and the second drain electrode DE2. For example, the third capacitor electrode SC3 is integrally formed with the second source electrode SE2 of the second transistor T2 to be electrically connected to the second source electrode SE2. The second source electrode SE2 can be electrically connected to the first capacitor electrode SC1 through a contact hole formed in the interlayer insulating layer 113 and the buffer layer 111. A contact hole which electrically connects the second source electrode SE2 and the first capacitor electrode SC1 can be disposed in a second area A2, but is not limited thereto. Therefore, the first capacitor electrode SC1 and the third capacitor electrode SC3 can be electrically connected to the second source electrode SE2 of the second transistor T2.

In the meantime, the third capacitor electrode SC3 can be formed of a reflective metal material.

When the light emitted from the light emitting diode LED travels by passing between the assembly lines 120 disposed below the light emitting diode LED, light is reflected from the third capacitor electrode SC3 to be extracted to the upper portion of the substrate 110.

The storage capacitor Cst stores a potential difference between the second gate electrode GE2 and the second source electrode SE2 of the second transistor T2 while the light emitting diode LED emits light, so that a constant current can be supplied to the light emitting diode LED. Accordingly, the storage capacitor Cst includes the first capacitor electrode SC1, the second capacitor electrode SC2, and the third capacitor electrode SC3 to store a voltage between the second gate electrode GE2 and the second source electrode SE2 of the second transistor T2. The first capacitor electrode SC1 is formed on the substrate 110 and is connected to the second source electrode SE2, and the second capacitor electrode SC2 is formed on the buffer layer 111 and the gate insulating layer 112 and is disposed on the same layer as the second gate electrode GE2. The third capacitor electrode SC3 is formed on the interlayer insulating layer 113 and is connected to the second source electrode SE2.

In the meantime, even though in FIG. 3, it is illustrated that the storage capacitor Cst is disposed only in an area corresponding to a protrusion of the assembly line 120, the storage capacitor Cst extends to an upper end of the protrusion of the assembly line 120 to be disposed in an area adjacent to the first area A1 of the sub pixel SP adjacent in the column direction.

The first passivation layer 114 is disposed on the first transistor T1, the second transistor T2, the third transistor T3, and the storage capacitor Cst. The first passivation layer 114 is an insulating layer which protects components below the first passivation layer 114 and can be configured by a single layer or a plurality of layers of silicon oxide (SiOx) or silicon nitride (SiNx), but is not limited thereto.

The lower planarization layer 115 is disposed on the first passivation layer 114. The lower planarization layer 115 can planarize an upper portion of the substrate 110 on which the plurality of transistors T1, T2, and T3 and the storage capacitor Cst are disposed. The lower planarization layer 115 can be configured by a single layer or a plurality of layers, and for example, can be formed of photoresist or an acrylic organic material, but is not limited thereto.

The second passivation layer 116 is disposed on the lower planarization layer 115. The second passivation layer 116 is an insulating layer which protects components below the second passivation layer 116, and can be configured by a single layer or a plurality of layers of silicon oxide (SiOx) or silicon nitride (SiNx), but is not limited thereto.

The connection electrode 150 and the plurality of assembly lines 120 are disposed on the second passivation layer 116.

The connection electrode 150 is an electrode which electrically connects the second transistor T2 and the pixel electrode PE. The connection electrode 150 can be electrically connected to the second source electrode SE2 which also serves as the third capacitor electrode SC3 through a contact hole formed in the second passivation layer 116, the lower planarization layer 115, and the first passivation layer 114.

The connection electrode 150 can be disposed in the second area A2. For example, the connection electrode 150 can be disposed between the light emitting diode LED and the pixel circuit of the sub pixel SP adjacent in the column direction. Therefore, the light emitting diode LED can be disposed between the connection electrode 150 and the driving transistor.

The connection electrode 150 can have a multi-layer structure formed by a first connection layer 150a and a second connection layer 150b. The first connection layer 150a is disposed on the second passivation layer 116 and the second connection layer 150b which covers the first connection layer 150a is disposed. The second connection layer 150b can be disposed to enclose all a top surface and side surfaces of the first connection layer 150a.

The second connection layer 150b is formed of a material which is more resistant to corrosion than the first connection layer 150a so that when the display device 100 is manufactured, the short defect due to the migration between the first connection layer 150a and the adjacent wiring line can be minimized. For example, the first connection layer 150a is formed of a conductive material, such as copper (Cu) or chrome (Cr), and the second connection layer 150b can be formed of molybdenum (Mo) or titanium molybdenum (MoTi), but are not limited thereto.

A plurality of assembly lines 120 is disposed on the second passivation layer 116.

The plurality of assembly lines 120 includes a plurality of first assembly lines 121 and a plurality of second assembly lines 122.

The plurality of first assembly lines 121 and the plurality of second assembly lines 122 extend in the column direction in each of the first sub pixel SP1, the second sub pixel SP2, and the third sub pixel SP3 and can be disposed to be spaced apart from each other with a predetermined interval.

The plurality of assembly lines 120 is disposed in an area overlapping the low potential power line VSS to be electrically connected to the low potential power line VSS. The low potential power line VSS is a wiring line which transmits a low potential power voltage to the light emitting diode LED. The low potential power line VSS and the plurality of assembly lines 120 can be electrically connected to each other. The plurality of assembly lines 120 is integrally formed with the low potential power line VSS. The low potential power line VSS can extend in the column direction in each of the plurality of sub pixels SP. For example, the low potential power line VSS can be disposed in each of the first sub pixel SP1, the second sub pixel SP2, and the third sub pixel SP3.

Each of the plurality of assembly lines 120 includes conductive layers 121a and 122a disposed on the second passivation layer 116 and clad layers 121b and 122b which are disposed on the conductive layers 121a and 122a and cover all the top surface and side surfaces of the conductive layers 121a and 122a.

The first assembly line 121 includes the first conductive layer 121a and the first clad layer 121b, and the second assembly line 122 includes the second conductive layer 122a and the second clad layer 122b.

The first conductive layer 121a and the second conductive layer 122a may not overlap the light emitting diode LED. For example, ends of the first conductive layer 121a and the second conductive layer 122a can be disposed at the outside from the end of the light emitting diode LED.

The first clad layer 121b of the first assembly line 121 can be disposed so as to cover the top surface and the side surfaces of the first conductive layer 121a, and the second clad layer 122b of the second assembly line 122 can be disposed so as to cover the top surface and the side surfaces of the second conductive layer 122a.

The first assembly line 121 and the second assembly line 122 can include protrusions protruding toward the light emitting diode LED. For example, the protrusion of the first assembly line 121 can be a portion of the first clad layer 121b extending to the center of the light emitting diode LED, between the first conductive layer 121a and the second conductive layer 122a. The protrusion of the second assembly line 122 can be a portion of the second clad layer 122b extending to the center of the light emitting diode LED, between the first conductive layer 121a and the second conductive layer 122a. At this time, each of the protrusion of the first assembly line 121 and the protrusion of the second assembly line 122 can be disposed so as to overlap an area corresponding to less than half of an area of the bottom surface of the light emitting diode LED.

Further, the protrusion of the first assembly line 121 and the protrusion of the second assembly line 122 can overlap the storage capacitor Cst.

The first conductive layer 121a and the second conductive layer 122a can be formed of the same material by the same process as the first connection layer 150a of the connection electrode 150. For example, the first conductive layer 121a and the second conductive layer 122a can be formed of a conductive material, such as copper (Cu) and chrome (Cr). The first clad layer 121b and the second clad layer 122b can be formed of the same material by the same process as the second connection layer 150b of the connection electrode 150. For example, the first clad layer 121b and the second clad layer 122b can be formed of a material which is more resistant to corrosion than the first conductive layer 121a and the second conductive layer 122a, for example, molybdenum (Mo) or titanium molybdenum (MoTi), but is not limited thereto.

The third passivation layer 117 is disposed on the connection electrode 150 and the assembly line 120. The third passivation layer 117 is an insulating layer which protects components below the third passivation layer 117 and can be configured by a single layer or a plurality of layers of silicon oxide (SiOx) or silicon nitride (SiNx), but is not limited thereto.

A partial area of the third passivation layer 117 can be open in an area adjacent to the plurality of light emitting diodes LED. For example, the third passivation layer 117 can expose a part of top surfaces of the first assembly line 121 and the second assembly line 122 in an area adjacent to one side surface of the plurality of light emitting diodes LED.

The plurality of light emitting diodes LED is disposed on the third passivation layer 117. Referring to FIGS. 3 and 4, the bottom surface of the light emitting diode LED is disposed to overlap the storage capacitor Cst between the first assembly line 121 and the second assembly line 122.

One or more light emitting diodes LED are disposed in one sub pixel SP. As illustrated in FIG. 3, two light emitting diodes LED can be disposed in one sub pixel SP. The light emitting diode LED is an element which emits light by the current. The light emitting diode LED can include a light emitting diode LED which emits red light, green light, and blue light and can implement light of various colors including white by a combination thereof. Further, light of various colors can be implemented using the light emitting diode LED which emits specific color light and a light conversion member which converts light from the light emitting diode LED into another color light.

The light emitting diode LED is supplied with a driving current from the second transistor T2 to emit light. The light emitting diode LED can include a red light emitting diode, a green light emitting diode, and a blue light emitting diode. For example, a light emitting diode LED disposed in the first sub pixel SP1 is a red light emitting diode, a light emitting diode LED disposed in the second sub pixel SP2 is a green light emitting diode, and a light emitting diode LED disposed in the third sub pixel SP3 can be a blue light emitting diode, but is not limited thereto.

At this time, the plurality of light emitting diodes LED disposed in one sub pixel SP can be connected in parallel. For example, one electrode of each of the plurality of light emitting diodes LED is connected to the source electrode SE2 of the second transistor T2 and another electrode can be connected to the same assembly line 120.

The light emitting diode LED can include a first light emitting diode 130 and a second light emitting diode 140. The light emitting diode LED disposed in each of the plurality of sub pixels SP can be disposed in the column direction. For example, as illustrated in FIG. 3, the second light emitting diode 140 can be disposed above the first light emitting diode 130.

The first light emitting diode 130 can emit the same color light as the second light emitting diode 140. In this case, the first light emitting diode 130 and the second light emitting diode 140 are the same type of light emitting diode LED so that the size of the first light emitting diode 130 can be equal to the size of the second light emitting diode 140. Here, the size of the light emitting diode LED can refer to an area of a bottom surface of the light emitting diode LED, a width on the cross section, a volume, or a height, but is not limited thereto.

Even though in FIG. 3, for the convenience of description, it is illustrated that two light emitting diodes LED are disposed in each of the plurality of sub pixels SP, the number of light emitting diodes LED which is disposed in each of the plurality of sub pixels SP is not limited thereto.

Referring to FIGS. 3 and 4, the light emitting diode 130 includes a first semiconductor layer 131, an emission layer 132, a second semiconductor layer 133, a first electrode 134, a second electrode 135, and an encapsulation layer 136.

The first semiconductor layer 131 is disposed on the third passivation layer 117 and the second semiconductor layer 133 is disposed on the first semiconductor layer 131. The first semiconductor layer 131 and the second semiconductor layer 133 can be layers formed by doping N-type and P-type impurities into a specific material. For example, the first semiconductor layer 131 and the second semiconductor layer 133 can be layers formed by doping P-type and N-type impurities into a material, such as gallium nitride (GaN), indium aluminum phosphide (InAlP), or gallium arsenide (GaAs). The P-type impurity can be magnesium (Mg), zinc (Zn), and beryllium (Be), and the N-type impurity can be silicon (Si), germanium (Ge), and tin (Sn), but are not limited thereto.

A part of the first semiconductor layer 131 can be disposed to outwardly protrude from the second semiconductor layer 133. A top surface of the first semiconductor layer 131 can be formed by a part overlapping a bottom surface of the second semiconductor layer 133 and a part disposed at an outside of the bottom surface of the second semiconductor layer 133. However, sizes and shapes of the first semiconductor layer 131 and the second semiconductor layer 133 can be modified in various forms, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 can be formed by a single layer or a multi-quantum well (MQW) structure, and for example, can be formed of indium gallium nitride (InGaN) or gallium nitride (GaN), but is not limited thereto.

The first electrode 134 which encloses a bottom surface and side surfaces of the first semiconductor layer 131 is disposed. The first electrode 134 is an electrode which electrically connects the first light emitting diode 130 and the assembly line 120. The first electrode 134 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the top surface of the second semiconductor layer 133. The second electrode 135 is an electrode which electrically connects a pixel electrode PE to be described below and the second semiconductor layer 133. The second electrode 135 can be formed of a conductive material, for example, a transparent conductive material, such as indium tin oxide (ITO) or indium zinc oxide (IZO), but is not limited thereto.

The encapsulation layer 136 which encloses at least a part of the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. The encapsulation layer 136 can be disposed so as to cover the emission layer 132, a part of a side surface of the first semiconductor layer 131 adjacent to the emission layer 132, and a part of a side surface of the second semiconductor layer 133 adjacent to the emission layer 132. The first electrode 134 and the second electrode 135 can be exposed from the encapsulation layer 136 and a contact electrode CE and a pixel electrode PE to be formed later and the first electrode 134 and the second electrode 135 can be electrically connected.

An adhesive layer AD can be disposed between the plurality of light emitting diodes LED and the third passivation layer 117 and the assembly line 120. The adhesive layer AD can be an organic film which temporarily fixes the light emitting diode LED during the self-assembly process of the light emitting diode LED. When the display device 100 is manufactured, if an organic film which covers the light emitting diode LED is formed, a part of the organic film is filled in a space between the light emitting diode LED and the third passivation layer 117 and the assembly line 120 to temporarily fix the light emitting diode LED onto the third passivation layer 117 and the assembly line 120. Thereafter, even though the organic film is removed, a part of the organic film which permeates under the light emitting diode LED remains without being removed to serve as an adhesive layer. The adhesive layer AD can be formed of an organic material, for example, photoresist or an acrylic organic material, but is not limited thereto.

The contact electrode CE is disposed on the side surface of the light emitting diode LED. The contact electrode CE is an electrode for electrically connecting the light emitting diode LED and the assembly line 120. The contact electrode CE can be disposed to enclose at least a part of the first semiconductor layer 131 and the first electrode 134 of the light emitting diode in an area overlapping the first assembly line 121 and the second assembly line 122. At this time, the contact electrode CE can be electrically connected to the first assembly line 121 and the second assembly line 122 exposed by the third passivation layer 117 in an area where the third passivation layer 117 is open.

In the meantime, the contact electrode CE can be configured by a conductive material such as copper (Cu), aluminum (Al), molybdenum (Mo), nickel (Ni), titanium (Ti), chrome (Cr), or an alloy thereof.

The upper planarization layer 119 is disposed on the light emitting diode LED and the contact electrode CE. The upper planarization layer 119 planarizes the third passivation layer 117 to fix the light emitting diode LED onto the substrate 110 together with the adhesive layer AD.

The upper planarization layer 119 can be configured by a single layer or a plurality of layers, and for example, can be formed of an acrylic organic material, but is not limited thereto. In the meantime, the upper planarization layer 119 includes a contact hole which exposes a part of the top surface of the light emitting diode LED. The pixel electrode PE is disposed in the contact hole of the upper planarization layer 119 to be electrically connected to the second electrodes 135 of the plurality of light emitting diodes LED.

The pixel electrode PE is disposed on the upper planarization layer 119.

The pixel electrode PE is an electrode which electrically connects the plurality of light emitting diodes LED and the connection electrode 150. The pixel electrode PE is electrically connected to the pixel circuit and disposed to extend to the first light emitting diode 130 and the second light emitting diode 140. For example, the pixel electrode PE extends to the first light emitting diode 130 to be connected to the second light emitting diode 140 and can be electrically connected to the connection electrode 150 and the second transistor T2 through the contact hole formed in the upper planarization layer 119.

The pixel electrode PE can be formed of a conductive material, for example, a transparent conductive material, such as indium tin oxide (ITO) or indium zinc oxide (IZO), but is not limited thereto.

Referring to FIGS. 3 and 4, the second light emitting diode 140 is disposed on the third passivation layer 117. The second light emitting diode 140 is disposed above the first light emitting diode 130 and is disposed in one sub pixel SP together with the first light emitting diode 130 and the pixel circuit.

The second light emitting diode 140 includes a first semiconductor layer, an emission layer, a second semiconductor layer, a first electrode, a second electrode, and an encapsulation layer. The first semiconductor layer, the emission layer, the second semiconductor layer, the second electrode, and the encapsulation layer of the second light emitting diode 140 can be substantially the same as the first semiconductor layer 131, the emission layer 132, the second semiconductor layer 133, the second electrode 135, and the encapsulation layer 136 of the first light emitting diode 130. Accordingly, a redundant description will be omitted.

The second light emitting diode 140 can be electrically connected to the first light emitting diode 130 and the pixel electrode PE extending from the pixel circuit through the contact hole formed in the upper planarization layer 119. Therefore, in one sub pixel SP, the first light emitting diode 130 and the second light emitting diode 140 can be electrically connected to the second transistor T2.

When the plurality of light emitting diodes is assembled using the assembly line, the plurality of assembly lines is disposed to be spaced apart from each other between the plurality of light emitting diodes. Therefore, when light downwardly traveling, among light emitted from the plurality of light emitting diodes, travels in the separated space formed between the assembly lines, the light is not extracted to the outside of the display device, but can be trapped in the display device or discharged below the display device. Therefore, there can be an issue in that the light extraction efficiency of the display device can be degraded or effected.

Therefore, in the display device 100 according to the exemplary embodiment of the present disclosure, the storage capacitor Cst is disposed so as to overlap the plurality of light emitting diodes LED so that the light emitted from the plurality of light emitting diodes LED is reflected from the storage capacitor Cst. Therefore, the light loss of light traveling between the assembly lines 120, among light emitted from the plurality of light emitting diodes LED can be suppressed or minimized. In the display device 100 according to the exemplary embodiment of the present disclosure, the reflectance of the light is improved to improve the light extraction efficiency, thereby reducing the power consumption of the display device 100.

In the meantime, in the case of a display device in which the plurality of light emitting diodes is assembled using the assembly line, unlike the other display device, a signal line, such as the assembly line, is additionally disposed so that a space for enlarging the area of the storage capacitor can be limited. Therefore, when the area of the storage capacitor is enlarged within a limited space, the aperture ratio of the pixel can be degraded, and it can be challenging to improve the resolution of the display device.

To address this issue, in the display device 100 according to the exemplary embodiment of the present disclosure, the storage capacitor Cst is disposed so as to overlap the plurality of light emitting diodes LED to ensure a pixel design area of the display device 100. For example, when the area of the storage capacitor Cst is maintained, the area of the sub pixel can be reduced as much as an overlapping area of the light emitting diode LED and the storage capacitor Cst. Further, for example, when the area of the storage capacitor Cst is maintained, the area of the storage capacitor Cst can be increased as much as an overlapping area of the light emitting diode LED and the storage capacitor Cst. Therefore, in the display device 100 according to the exemplary embodiment of the present disclosure, a high resolution display device having a high pixel per inch (PPI) is implemented or a capacitance of the storage capacitor Cst is increased.

Further, during the manufacturing process of the display device, an ART test for detecting a defect of the driving circuit early before transferring the light emitting diode is performed. The ART test is performed by aligning liquid crystals of a modulator by a capacitance formed between the modulator and a driving circuit and a capacitor, by applying a test voltage to the modulator and by detecting a degree of transmitting the light by the aligned liquid crystals. Therefore, the sensitivity of the test can depend on the magnitude of the capacitance formed between the electrode of the modulator and the capacitor. Therefore, when the capacitor area is reduced, the capacity of the capacitor is reduced to degrade the sensing characteristic so that the signal sensitivity of the modulator is degraded. Accordingly, the test result can be erroneously determined. Therefore, when a defective panel is determined as a normal panel, a plurality of normal light emitting diodes is assembled in the defective panel so that there are problems in that a process efficiency is degraded and an expensive light emitting diode can be discarded. Further, when the normal panel is determined as a defective panel, there can be a limitation in that the normal panel is discarded.

To address this issue, in the display device 100 according to the exemplary embodiment of the present disclosure, the storage capacitor Cst is disposed so as to overlap the plurality of light emitting diodes LED to increase the area of the storage capacitor Cst. Therefore, when the ART test is performed, a capacitance between the display panel PN and the modulator can be improved to enhance a sensitivity of the signal of the modulator, and the detectability and the reliability of the ART test can be improved. Therefore, the defective panel can be normally discarded, and the cost of discarding the light emitting diode which is transferred onto the defective panel together can be saved. Therefore, the process efficiency can be increased and the production yield can be improved.

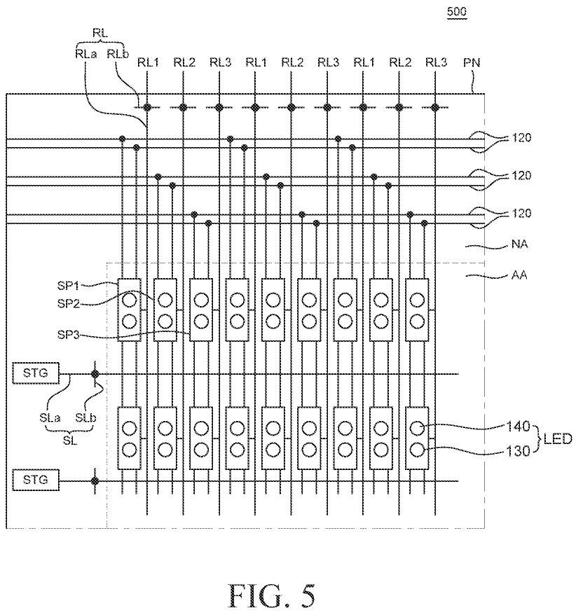

FIG. 5 is a schematic diagram of a display device according to another exemplary embodiment of the present disclosure. Particularly, FIG. 5 is an enlarged plan view of the display panel PN. The difference between a display device 500 of FIG. 5 and the display device 100 of FIGS. 1 to 4 is a plurality of scan lines SL and a plurality of reference lines RL, but the other configuration is substantially the same, so that a redundant description will be omitted or may be briefly provided. In FIG. 5, for the convenience of illustration, a plurality of light emitting diodes LED, a plurality of scan lines SL, a plurality of reference lines RL, a plurality of stages STG, and a plurality of assembly lines 120 are illustrated.

Referring to FIG. 5, the display panel PN includes an active area (or display area) AA in which a plurality of light emitting diodes LED is disposed and a non-active area (or non-display area) NA. The non-active area NA can surround the active area AA completely or only in part, and multiple non-active areas NA can be provided adjacent to the active area AA.

A plurality of stages STG is disposed at one side of the non-active area NA. The plurality of stages STG is a configuration of a gate driver GD and outputs a scan signal SCAN to a plurality of scan lines SL. The plurality of stages STG is connected to a plurality of scan lines SL disposed in the active area AA and the non-active area NA.

The plurality of scan lines SL includes a first line part SLa extending in the first direction in the active area AA and the non-active area NA. In FIG. 5, the first line part SLa of the plurality of scan lines SL can be connected to the third gate electrode GE3 of the third transistor T3, as illustrated in FIG. 2.

In the meantime, the scan line SL can include a first line part SLa which is disposed in the non-active area NA and extends in the first direction and a first protruding part SLb extending in the second direction intersecting the first direction.

A plurality of reference lines RL is disposed in the active area AA and the non-active area NA.

The plurality of reference lines RL includes a second line part RLa extending in the second direction in the active area AA and the non-active area NA. The plurality of reference lines RL includes a first reference line RL1, a second reference line RL2, and a third reference line RL3. The first reference line RL1 can be electrically connected to the first sub pixel SP1. The second reference line RL2 and the third reference line RL3 can be electrically connected to the second sub pixel SP2 and the third sub pixel SP3, respectively. The second line part RLa of the plurality of reference lines RL can be connected to the third drain electrode of the third transistor T3 in the first sub pixel SP1, the second sub pixel SP2, and the third sub pixel SP3.

In the meantime, the plurality of reference lines RL is disposed in the non-active area NA, and can include a second protruding part RLb which extends in the first direction intersecting the second direction from the second line part RLa.

A plurality of assembly lines 120 is disposed in the active area AA and the non-active area NA. The plurality of assembly lines 120 can be disposed to be spaced apart from each other below the plurality of light emitting diodes LED disposed in the first sub pixel SP1, the second sub pixel SP2, and the third sub pixel SP3 in the active area AA.

Further, the ends of the plurality of assembly lines 120 can overlap the end of the display panel PN in the non-active area NA.

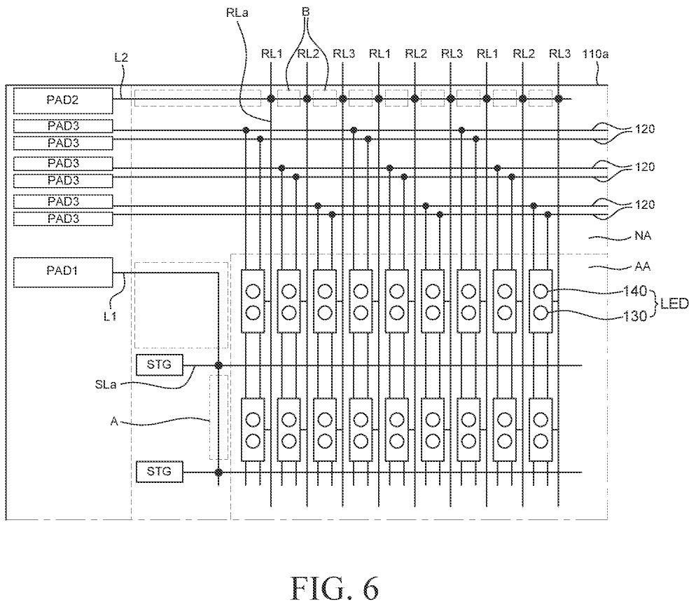

Hereinafter, a manufacturing method of the display device (e.g., 100 or 500) according to another exemplary embodiment of the present disclosure will be described with reference to FIG. 6.

FIG. 6 is a schematic diagram for explaining a manufacturing process of a display device according to another exemplary embodiment of the present disclosure. Particularly, FIG. 6 is a plan view of a mother glass 110a before being cut in the unit of display panel. In FIG. 6, for the convenience of drawing, the plurality of light emitting diodes LED, the plurality of scan lines SL, the plurality of reference lines RL, the plurality of assembly lines 120, the first line L1, the second line L2, the plurality of stages STG, the first pad PAD1, the second pad PAD2, and the plurality of assembly pads PAD3 are illustrated.

Referring to FIG. 6, the mother glass 110a on which a plurality of display panels is formed is disposed.

A first pad PAD1, a second pad PAD2, and a plurality of assembly pads PAD3 are disposed on the mother glass 110a. The first pad PAD1, the second pad PAD2, and the plurality of assembly pads PAD3 can be simultaneously formed with the components formed in the active area AA and the non-active area NA or individually formed.

A first line L1 is disposed between the first pad PAD1 and the plurality of stages STG. The first line L1 can be disposed between the first line parts SLa of the plurality of scan lines SL in the second direction. At this time, the first line LI can be electrically connected to the plurality of stages STG and the first line parts SLa of the plurality of scan lines SL disposed in the first direction. Therefore, the first pad PAD1 can be connected to the third gate electrodes GE3 of the plurality of third transistors T3 (see FIG. 3) disposed on the mother glass 110a.

The second line L2 is disposed between the second pad PAD2 and the plurality of reference lines RL. The second line L2 can be disposed between the second line parts RLa of the plurality of reference lines RL in the first direction. At this time, the second line L2 can be electrically connected to the second line parts RLa of the plurality of reference lines RL disposed in the second direction. Therefore, the second pad PAD2 can be connected to the third drain electrodes DE3 of the plurality of third transistors T3 (see FIG. 3) disposed on the mother glass 110a.

The plurality of assembly pads PAD3 can be electrically connected to the plurality of assembly lines 120 disposed on the mother glass 110a. Specifically, the plurality of assembly pads PAD3 can be connected to the plurality of assembly lines 120 disposed below the plurality of light emitting diodes LED disposed in the first sub pixel SP1, the second sub pixel SP2, and the third sub pixel SP3.

In the meantime, the first line L1 and the second line L2 can be formed simultaneously with components formed in the active area AA and the non-active area NA. For example, the first line L1 and the second line L2 can be formed on the same layer with the same material as the connection electrode 150, but are not limited thereto and can be individually formed, respectively.

Next, the first pad PAD1 and the second pad PAD2 can input a ground voltage to a plurality of storage capacitors Cst disposed on the mother glass 110a through the first line L1 and the second line L2. For example, the plurality of scan lines SL shares the first pad PAD1 and the first line L1 to simultaneously drive the plurality of third transistors T3 (see FIG. 3). Further, the plurality of reference lines RL shares the second pad PAD2 and the second line L2 to apply the ground voltage to the second source electrode SE2 of the second transistor T2 which also serves as the third capacitor electrode SC3 (see FIG. 3).

Next, an assembly signal is applied to the plurality of assembly pads PAD3 in a state in which the ground voltage is applied to the storage capacitor Cst to self-assemble the plurality of light emitting diodes LED.

Next, when the self-assembly of the plurality of light emitting diodes LED is completed, the first line L1 and the first pad PAD1, the second line L2 and the second pad PAD2, and a plurality of assembly lines 120 and the assembly pad PAD3 can be separated from each other. At this time, the first line L1 and the first pad PAD1, the second line L2 and the second pad PAD2, and a plurality of assembly lines 120 and the assembly pad PAD3 can be cut together with the mother glass 110a during a process of cutting the mother glass 110a in the unit of display panels, but is not limited thereto.

Further, the first line L1 disposed between the plurality of stages STG and the plurality of scan lines SL and the second line L2 disposed between the plurality of reference lines RL can be separated by a laser process or an etching process, respectively. For example, as illustrated in FIG. 6, the first line L1 can be removed from the area A disposed between the plurality of stages STG. Therefore, as illustrated in FIG. 5, the plurality of scan lines SL can include a first protruding part SLb which is formed from the first line L1 and is disposed in a direction intersecting the first line part SLa. Further, the second line L2 can be removed from an area B disposed between the plurality of reference lines RL. Therefore, the plurality of reference lines RL can include a second protruding part RLb which is formed from the second line and is disposed in a direction intersecting the second line part RLa.

In a display device 500 according to another exemplary embodiment of the present disclosure, the storage capacitor Cst is disposed to overlap the plurality of light emitting diodes LED to suppress the light loss of light traveling between the assembly lines 120, among light emitted from the plurality of light emitting diodes LED. Therefore, the light extraction efficiency is improved and the power consumption of the display device can be reduced.

Further, in the display device 500 according to another exemplary embodiment of the present disclosure, the storage capacitor Cst is disposed so as to overlap the plurality of light emitting diodes LED to ensure a pixel design area of the display device. Therefore, a high resolution display device having a high PPI can be implemented or a capacitance of the storage capacitor Cst can be increased.

Further, in the display device 500 according to another exemplary embodiment of the present disclosure, the storage capacitor Cst is disposed so as to overlap the plurality of light emitting diodes LED to increase the area of the storage capacitor Cst. Therefore, the detectability and the reliability of the ATR test can be improved to increase the process efficiency and improve a production yield.

Further, in the display device 500 according to another exemplary embodiment of the present disclosure, when an assembly signal is applied to the assembly line 120 during the assembling process of a plurality of light emitting diodes LED, a noise which can be caused in the storage capacitor Cst which overlaps the plurality of assembly lines 120 can be shielded. For example, in the display device 500 according to another exemplary embodiment of the present disclosure, the plurality of scan lines SL and the plurality of stages STG are electrically connected to simultaneously drive the plurality of pixel circuits. The plurality of reference lines RL is electrically connected to apply the ground voltage through the turned-on second transistor T2. Therefore, a noise which can be generated due to the interference between the storage capacitor Cst which is floated at the time of the self-assembly and the plurality of assembly lines can be shielded to block the defect generated during the self-assembling process of the plurality of light emitting diodes LED. Therefore, in the display device 500 according to another exemplary embodiment of the present disclosure, the assembly force of the light emitting diode LED can be improved and a production yield can be improved.

The exemplary embodiments of the present disclosure can also be described as follows:

According to an aspect of the present disclosure, there is provided a display device. The display device includes a substrate including an active area in which a plurality of sub pixels is disposed and a non-active area, a first assembly line and a second assembly line which are disposed in the plurality of sub pixels on the substrate and are disposed to be spaced apart from each other, a light emitting diode which is disposed in the plurality of sub pixels and is disposed on the first assembly line and the second assembly line, and a capacitor disposed below the first assembly line and the second assembly line, the capacitor is disposed so as to overlap a separated space between the first assembly line and the second assembly line.

The capacitor can be disposed so as to overlap the light emitting diode.

A bottom surface of the light emitting diode can overlap the capacitor in an area between the first assembly line and the second assembly line.

The first assembly line and the second assembly line can include a protrusion protruding toward an area overlapping the light emitting diode and the protrusion can be disposed so as to overlap the capacitor.

The display device can further include a transistor disposed on the substrate, and a light shielding layer disposed between the transistor and the substrate. The capacitor can include a first capacitor electrode disposed on the same layer as the light shielding layer, a second capacitor electrode disposed on the same layer as a gate electrode of the transistor, and a third capacitor electrode disposed on the same layer as a source electrode and a drain electrode of the transistor.

The display device can further include a plurality of transistors disposed on the substrate in each of the plurality of sub pixels, the each of the plurality of sub pixels can include a first area in which the plurality of transistors is disposed and a second area which is extended from the first area and have the capacitor disposed therein.

The display device can further include a driving transistor disposed on the substrate, a pixel electrode which is disposed on the light emitting diode to be electrically connected to the light emitting diode, and a connection electrode which connects the pixel electrode and the driving transistor, the light emitting diode can overlap an area between an area in which the connection electrode is disposed and an area in which the driving transistor is disposed.

The display device can further include a plurality of scan lines which is connected to the plurality of sub pixels, the plurality of scan lines can include a first line part extending in a first direction in the active area and the non-active area, and a first protruding part which is disposed in the non-active area and extends in a second direction intersecting the first direction from the first line part.

The display device can further include a sensing transistor disposed on the substrate. The plurality of scan lines can be connected to a gate electrode of the sensing transistor.

The display device can further include a plurality of reference lines which is connected to the plurality of sub pixels, the plurality of reference lines can include a second line part extending in the second direction in the active area and the non-active area, and a second protruding part which is disposed in the non-active area and extends in the first direction from the second line part.

The display device can further include a sensing transistor disposed on the substrate. The plurality of reference lines can be connected to a drain electrode of the sensing transistor.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure.

What is claimed is:

1. A display device, comprising:
a substrate including an active area and a non-active area, the active area including a plurality of sub pixels;
a first assembly line and a second assembly line both disposed in the plurality of sub pixels on the substrate and being separated from each other to form a separated space;
a light emitting diode disposed in the plurality of sub pixels and disposed on the first assembly line and the second assembly line; and
a capacitor disposed below the first assembly line and the second assembly line,
wherein the capacitor is disposed so as to overlap the separated space between the first assembly line and the second assembly line.

2. The display device according to claim 1, wherein the capacitor is disposed so as to overlap the light emitting diode.

3. The display device according to claim 1, wherein a bottom surface of the light emitting diode overlaps the capacitor in an area between the first assembly line and the second assembly line.

4. The display device according to claim 1, wherein the first assembly line and the second assembly line include a protrusion protruding toward an area overlapping the light emitting diode, and the protrusion is disposed so as to overlap the capacitor.

5. The display device according to claim 4, further comprising:
a transistor disposed on the substrate; and
a light shielding layer disposed between the transistor and the substrate.

6. The display device according to claim 5, wherein the capacitor includes:
a first capacitor electrode disposed on a same layer as the light shielding layer;
a second capacitor electrode disposed on a same layer as a gate electrode of the transistor; and
a third capacitor electrode disposed on a same layer as a source electrode and a drain electrode of the transistor.

7. The display device according to claim 1, further comprising:
a plurality of transistors disposed on the substrate in each of the plurality of sub pixels,
wherein each of the plurality of sub pixels includes a first area having the plurality of transistors disposed therein, and a second area extended from the first area and having the capacitor disposed therein.

8. The display device according to claim 1, further comprising:
a driving transistor disposed on the substrate;
a pixel electrode disposed on the light emitting diode to be electrically connected to the light emitting diode; and
a connection electrode connecting the pixel electrode and the driving transistor.

9. The display device according to claim 8, wherein the light emitting diode overlaps an area between an area in which the connection electrode is disposed and an area in which the driving transistor is disposed.

10. The display device according to claim 1, further comprising:
a plurality of scan lines connected to the plurality of sub pixels,
wherein the plurality of scan lines includes:
a first line part extending in a first direction in the active area and the non-active area; and
a first protruding part disposed in the non-active area and extending in a second direction intersecting the first direction from the first line part.

11. The display device according to claim 10, further comprising:
a sensing transistor disposed on the substrate,
wherein the plurality of scan lines is connected to a gate electrode of the sensing transistor.

12. The display device according to claim 11, further comprising:
a plurality of reference lines connected to the plurality of sub pixels,
wherein the plurality of reference lines includes:
a second line part extending in the second direction in the active area and the non-active area; and
a second protruding part disposed in the non-active area and extending in the first direction from the second line part.

13. The display device according to claim 12, wherein the plurality of reference lines is connected to a drain electrode of the sensing transistor.

14. The display device according to claim 1, wherein the light emitting diode includes a first electrode, a first semiconductor layer, an emission layer, a second semiconductor layer and a second electrode disposed on top of each other.

15. The display device according to claim 1, wherein each of the plurality of sub pixels includes a plurality of light emitting diodes connected in parallel.
